(19) United States
(12) Patent Application Publication
(10) Pub. No.: US 2003/0235042 A1
(43) Pub. Date: Dec. 25, 2003

(54) Carrier card and method

(76) Inventors: Jeffrey M. Harris, Chandler, AZ (US); Robert Tufford, Chandler, AR (US)

Correspondence Address: MOTOROLA, INC., CORPORATE LAW DEPARTMENT - #56-238, 3102 NORTH 56TH STREET, PHOENIX, AZ, 85018, US

(21) Appl. No.: 10/178,650

(22) Filed: Jun. 24, 2002

(51) Int. Cl. H05K 5/00; H05K 5/04; H05K 5/06

(52) U.S. Cl. 361/752

(57) ABSTRACT

A computer system (100) includes a carrier card (102) and at least one mini-PCI card (104) coupled to the carrier card (102), where the mini-PCI card (104) interfaces with the computer system (100) via the carrier card (102). The carrier card (102) can include a bridging module (108) coupled to the mini-PCI card (104) where the mini-PCI card (104) communicates with the computer system (100) via the bridging module (108). The carrier card (102) can have one of a VMEbus, CompactPCI, PMC, PCI, ATCA and APS form factor.

### BACKGROUND OF THE INVENTION

Currently, in order to incorporate mini-PCI (Peripheral Component Interconnect) card functionality into existing computer systems, a mini-PCI connector must be incorporated onto a printed circuit board or the discrete components of the mini-PCI card must be incorporated directly onto the printed circuit board. This configuration limits flexibility in the use of min-PCI cards. Also, it is desirable to fit additional functionality into smaller spaces, while maintaining the flexibility of a modular type system. Mini-PCI cards offer modular functionality while taking up relatively little space. Prior art computer systems do not have the capability to add mini-PCI card functionality in a modular fashion.

Accordingly, there is a significant need for an apparatus and method that overcomes the deficiencies of the prior art outlined above.

### BRIEF DESCRIPTION OF THE DRAWINGS

Referring to the drawing:

FIG. 1 depicts a computer system according to one embodiment of the invention;

FIG. 2 depicts a computer system according to another embodiment of the invention;

FIG. 3 depicts a computer system according to yet another embodiment of the invention;

FIG. 4 depicts a computer system according to still another embodiment of the invention;

FIG. 5 depicts a representation of a form factor of a mini-PCI card according to an embodiment of the invention; and

FIG. 6 depicts a representation of a form factor of a mini-PCI card according to another embodiment of the invention.

It will be appreciated that for simplicity and clarity of illustration, elements shown in the drawing have not necessarily been drawn to scale. For example, the dimensions of some of the elements are exaggerated relative to each other. Further, where considered appropriate, reference numerals have been repeated among the Figures to indicate corresponding elements.

### DESCRIPTION OF THE PREFERRED EMBODIMENTS

In the following detailed description of exemplary embodiments of the invention, reference is made to the accompanying drawings, which illustrate specific exemplary embodiments in which the invention may be practiced. These embodiments are described in sufficient detail to enable those skilled in the art to practice the invention, but other embodiments may be utilized and logical, mechanical, electrical and other changes may be made without departing from the scope of the present invention. The following detailed description is, therefore, not to be taken in a limiting sense, and the scope of the present invention is defined only by the appended claims.

In the following description, numerous specific details are set forth to provide a thorough understanding of the invention. However, it is understood that the invention may be practiced without these specific details. In other instances, well-known circuits, structures and techniques have not been shown in detail in order not to obscure the invention.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact. However, “coupled” may mean that two or more elements are not in direct contact with each other, but yet still co-operate or interact with each other.

For clarity of explanation, the embodiments of the present invention are presented, in part, as comprising individual functional blocks. The functions represented by these blocks may be provided through the use of either shared or dedicated hardware, including, but not limited to, hardware capable of executing software. The present invention is not limited to implementation by any particular set of elements, and the description herein is merely representational of one embodiment.

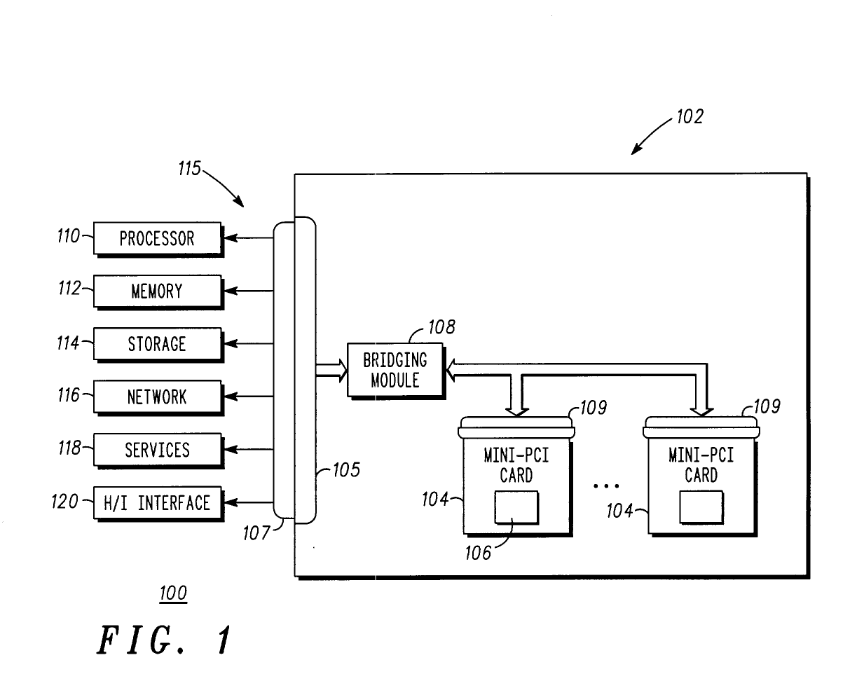

FIG. 1 depicts a computer system 100 according to one embodiment of the invention. As shown in FIG. 1, computer system 100 can include a carrier card 102 having one or more mini-PCI cards 104. Carrier card 102 can be coupled to one or more components on host side 115 of computer system 100 including processor 110 for processing algorithms stored in memory 112. Memory 112 comprises control algorithms, and can include, but is not limited to, random access memory (RAM), read only memory (ROM), flash memory, electrically erasable programmable ROM (EEPROM), and the like. Memory 112 can contain stored instructions, tables, data, and the like, to be utilized by processor 110. Computer system 100 can also include storage 114, which can include, for example, hard drive, flash memory, floppy disks and disk drives, CD-ROM, DVD, and the like.

Carrier card 102 can also be coupled to one or more networks 116 and services 118. Network 116 can include, for example and without limitation, VERSAmodule Eurocard (VMEbus), Peripheral Component Interconnect (PCI and PCI-X), RapidIO™, Serial RapidIO™, 3GIO™, Infiniband™, Hypertransport™, FibreChannel™, Ethernet™ networks, and the like. Services 118 can be an encapsulation of some functionality that is of use to one or more service-using entities (current or anticipated). A service can provide access to information or perform some computation. Services 118 also provide a desired functionality to a human user.

Computer system can also include human interface (H/I) elements 120, which can include, without limitation, elements such as a display, a multi-position controller, one or more control knobs, one or more indicators such as bulbs or light emitting diodes (LEDs), one or more control buttons, one or more speakers, a microphone, and any other H/I elements 120 required by computer system 100. H/I elements 120 can request and display content and data including, application data, position data, personal data, email, audio/video, and the like. The invention is not limited by the (H/I) elements 120 described above. As those skilled in the art will appreciate, the (H/I) elements 120 outlined above are meant to be representative and to not reflect all possible (H/I) elements that may be employed.

Carrier card 102 can include one or more mini-PCI cards 104 coupled to an adaptor connector 105, where adaptor connector 105 is coupled to, and interfaces with, connector interface 107 of computer system 100. Carrier card 102 interfaces with host side 115 of computer system 100 via adaptor connector 105 and connector interface 107. In an embodiment of the invention, adaptor connector 105 can be an integral part of carrier card 102. Mini-PCI card 104 is coupled to, and interfaces with carrier card 102 via mini-PCI card interface 109. Mini-PCI card 104 interfaces with computer system 100 via carrier card 102.

Mini-PCI card 104 can be an alternate implementation for a small form factor PCI card. Mini-PCI cards are known in the art with mechanical, electrical and configuration standards set out in the Mini PCI Specification revision 1 or later and the PCI Local Bus Specification revision 2.3 or later as promulgated by the PCI Special Interest Group, 5300 N.E. Elam Young Parkway, Hillsboro, Oreg.

In an embodiment of the invention, carrier card can include bridging module 108 coupled to mini-PCI card 104. Bridging module 108 can be hardware and/or software to provide an interface between any number of mini-PCI cards 104 on carrier card 102 and other elements on host side 115 of computer system 100, such as processor 110, memory 112, network 116, and the like. Bridging module 108 is known in the art and can facilitate communication between mini-PCI card 104 and computer system 100. Mini-PCI card 104 can communicate with bridging module 108 using a network protocol, such as a parallel multi-drop network, which can use for example, a Peripheral Interconnect-X (PCI-X™) based protocols. Examples of variants of PCI-X protocols, without limitation, include 133 MHz 64-bit PCI-X, 100 MHz 64-bit PCI-X, and the like. Mini-PCI card 104 can also communicate with bridging module 108 using any variant of older PCI based protocols (a subset of PCI-X based protocols), for example and without limitation, 66 MHz 64-bit PCI down to 33 MHz 32-bit PCI, and the like. Presently, mini-PCI card 104 can communicate with bridging module 108 using the 33 MHz 32-bit PCI protocol. However, other PCI and PCI-X protocols are within the scope of the invention.

Bridging module 108 allows mini-PCI card 104 to bridge across speed and load domains different from the one used by mini-PCI card 104 in addition to network protocols different from the PCI based protocol used by mini-PCI card 104. As an example of a difference in network protocols, carrier card 102 can be coupled to host side 115 of computer system 100, where host side 115 uses a VMEbus network architecture using any of the VMEbus protocols known in the art. For example, VMEbus based protocols can include, but are not limited to, Single Cycle Transfer protocol (SCT), Block Transfer protocol (BLT), Multiplexed Block Transfer protocol (MBLT), Two Edge VMEbus protocol (2eVME) and Two Edge Source Synchronous Transfer protocol (2eSST). While mini-PCI card 104 uses a version of a PCI based protocol, bridging module 108 allows mini-PCI card 104 to communicate with host side 115 of computer system 100.

As an example of a speed domain difference, host side 115 of computer system 100 can uses a PCI based protocol, for example a PCI based protocol, that is faster than the 33 MHz 32-bit PCI protocol used by mini-PCI card 104. Bridging module 108 can allow mini-PCI card 104 to communicate with host side 115 without slowing down the host side 115 PCI protocol based network. In effect, bridging module 108 allows one or more mini-PCI cards 104 to run at 33 MHz 32-bit without the entire host side 115 network being slowed down to this speed and data transfer rate.

As an example of a load domain difference, if host side 115 of computer system 100 uses a network protocol that only allows a limited number of cards on the bus, bridging module 108 allows any number of mini-PCI cards 104 to be added to the bus while the bus only sees one load. The use of bridging modules 108 to bridge speed and load domains is known in the art.

Carrier card 102 allows the functionality of one or more mini-PCI cards 104 to be incorporated into computer system 100 with all of the advantages of a mini-PCI card, including small form factor, limited heat generation, low power consumption, and the like. Functionality of mini-PCI card 104 can be included in one or more modules 106 coupled to mini-PCI card 104. Modules 106 can include hardware and/or software components. Examples of mini-PCI card functionality can include, but are not limited to, processors, memory, storage, modems, wireless communication means including Bluetooth, 802.11, and the like, local area network (LAN) and wide area network (WAN) capabilities, and the like.

In an embodiment of the invention, carrier card 102 functions to interface one or more mini-PCI cards 104 with host side 115 of computer system 100, where host side 115 can be designed to accept a carrier card 102 with a given form factor. The following figures illustrate several implementations of embodiments of the invention. The implementations shown are exemplary and not meant to be limiting of the invention. Other form factors, adaptor connectors, connector interfaces, and the like are within the scope of the invention.

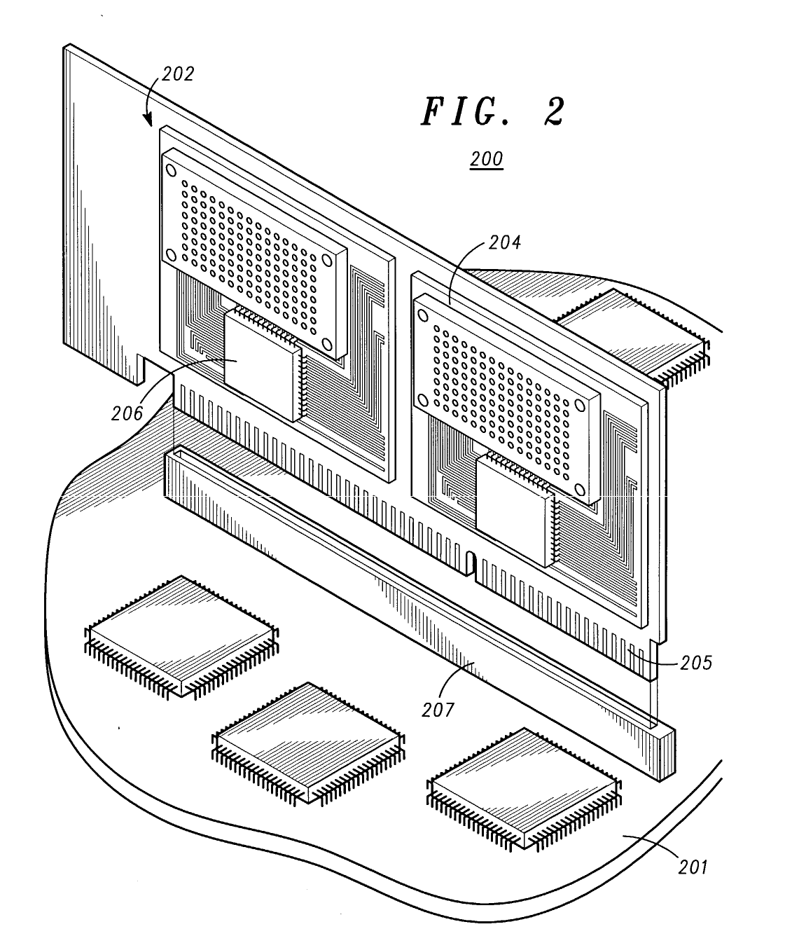

FIG. 2 depicts a computer system 200 according to another embodiment of the invention. As shown in FIG. 2, a host board 201, which can be for example a motherboard, and the like, is designed to interface with carrier card 202. In this embodiment, carrier card 202 has a PCI form factor. Carrier card 202 with a PCI form factor has an adaptor connector 205 configured as a PCI adaptor connector. Also, host board 201 of computer system 200 includes connector interface 207, which is a PCI connector interface. PCI form factor, PCI adaptor connector, PCI connector interface, including mechanical dimensions, electrical specifications, and the like are known in the art and set forth in the PCI Local Bus Specification revision 2.3 or later as promulgated by the PCI Special Interest Group, 5300 N.E. Elam Young Parkway, Hillsboro, Oreg.

As shown in FIG. 2, carrier card 202 includes two mini-PCI cards 204. However, any number of mini-PCI cards 204 is within the scope of the invention. Mini-PCI card 204 can have one or more modules 206 as described above to add functionality to mini-PCI cards 204 and computer system 200. In an embodiment of the invention, a bridging module (not shown for clarity) can be included coupled to carrier card 202 as described above. Mini-PCI cards 204 are coupled to adaptor connector 205, and adaptor connector is designed to interlock with connector interface 207. Mini-PCI card 204 can communicate with computer system 200 via carrier card 202.

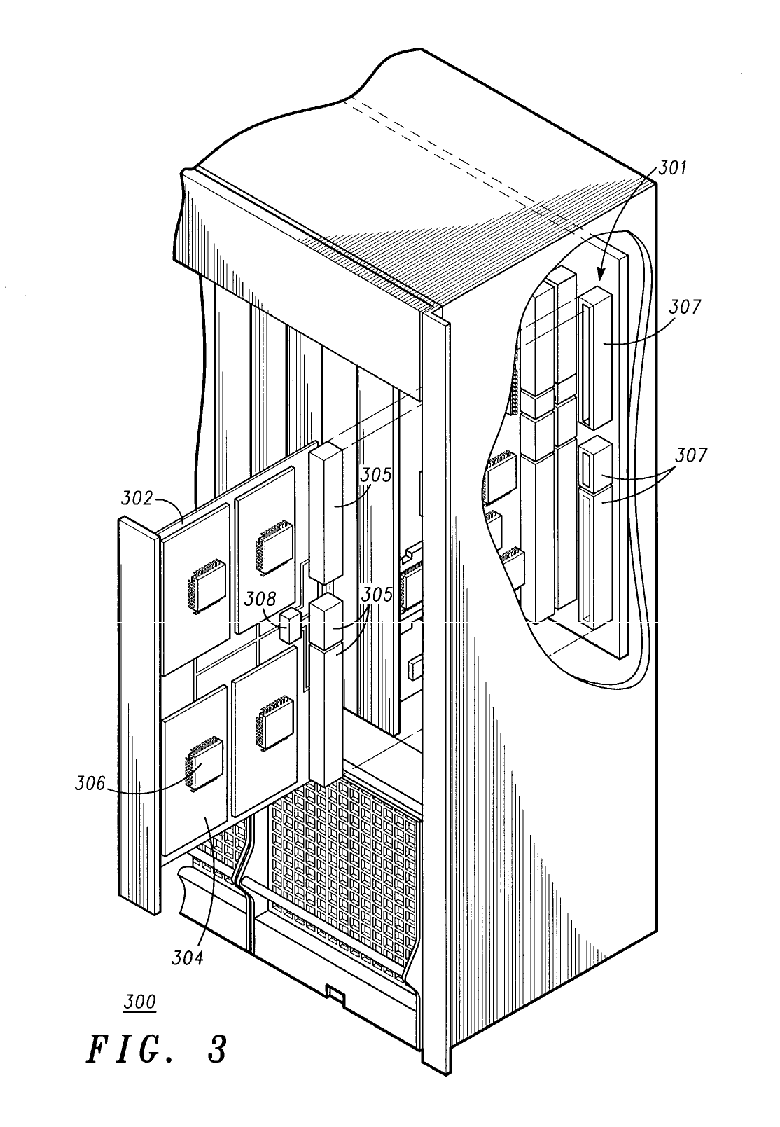

FIG. 3 depicts a computer system 300 according to yet another embodiment of the invention. As shown in FIG. 3, carrier card 302 can be a VMEbus board and have a VMEbus board form factor. Computer system 300 is a VMEbus network. Adaptor connector 305 can be VMEbus connectors and connector interface 307 can be VMEbus connectors on the backplane 301 of a VMEbus chassis designed to receive carrier card 302 having a VMEbus form factor. In the embodiment shown in FIG. 3, bridging module 308 is included coupled to carrier card 302, where bridging module 308 is also coupled to mini-PCI cards 304 having modules 306. VMEbus network, VMEbus form factor, VMEbus adaptor connector, VMEbus connector interface, including mechanical dimensions, electrical specifications, and the like, are known in the art and set forth in the ANSI/VITA 1-1994 and ANSI/VITA 1.1-1997 standards promulgated by the VMEbus International Trade Association (VITA), P.O. Box 19658, Fountain Hills, Ariz., 85269 (where ANSI stands for American National Standards Institute).

Although four mini-PCI cards 304 are shown, any number of mini-PCI cards 304 is within the scope of the invention. Mini-PCI cards 304 are coupled to adaptor connector 305, and adaptor connector 305 is designed to interlock with connector interface 307. Mini-PCI cards 304 can communicate with computer system 300 via carrier card 302.

In another embodiment, FIG. 3 can represent carrier card 302 with a CompactPCI® form factor. In this embodiment, adaptor connector 305 and connector interface 307 conform to CompactPCI standards. Compact PCI form factor, CompactPCI adaptor connector, CompactPCI connector interface, including mechanical dimensions, electrical specifications, and the like, are known in the CompactPCI Specification, by PCI Industrial Computer Manufacturers Group (PCIMG™), 301 Edgewater Place, Suite 220, Wakefield, Mass.

In yet another embodiment, FIG. 3 can represent carrier card 302 with an Advanced Telecommunications Computer Architecture (ATCA™) form factor. In this embodiment, adaptor connector 305 and connector interface 307 conform to ATCA standards. ATCA form factor, ATCA adaptor connector, ATCA connector interface, including mechanical dimensions, electrical specifications, and the like, are known in the art and set forth in the PCI Industrial Computer Manufacturers Group (PICMG) Specification 3.0.

In still another embodiment of the invention, FIG. 3 can represent carrier card 302 with an Advanced Packaging System (APS) form factor. In this embodiment, adaptor connector 305 and connector interface 307 conform to APS standards. APS form factor, APS adaptor connector, APS connector interface, including mechanical dimensions, electrical specifications, and the like, are known in the art and set forth in the ANSI/VITA Specification 34.

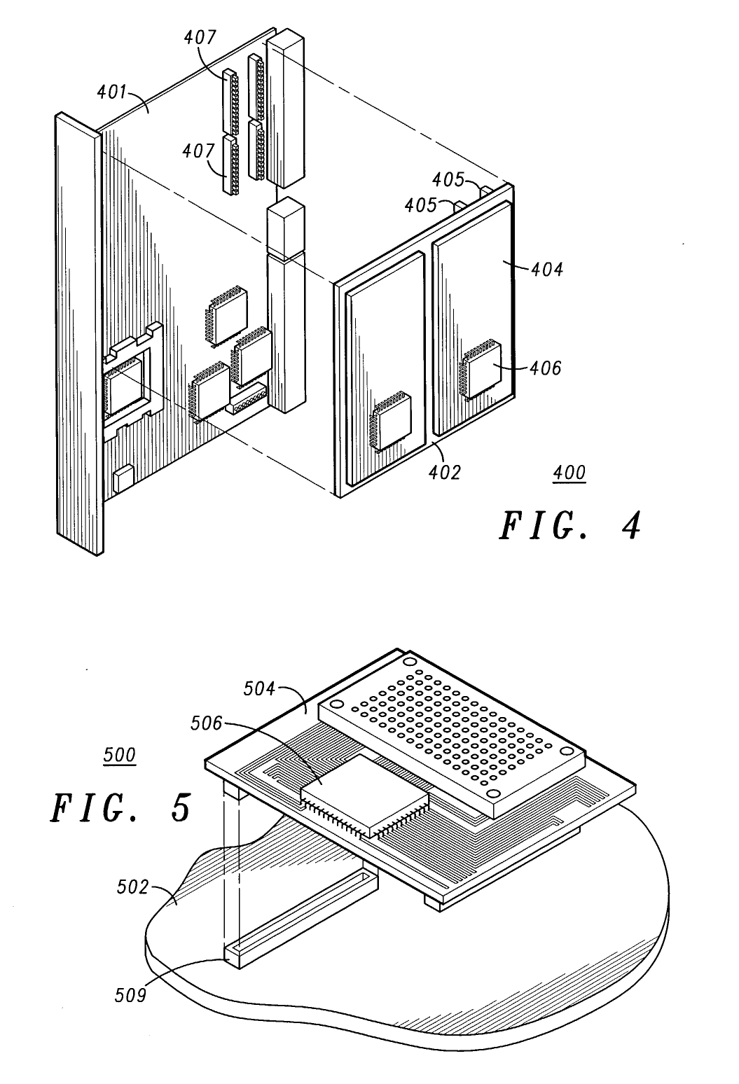

FIG. 4 depicts a computer system 400 according to still another embodiment of the invention. As shown in FIG. 4, carrier card 402 can be a mezzanine board designed to be coupled to host board 401. In this embodiment, host board can be a VMEbus board having a VMEbus form factor as described above. In general, mezzanine boards are deployed on a variety of electronics module host boards 401 to provide additional functionality, and the like.

Although any type of mezzanine board is within the scope of the invention, an exemplary embodiment of a carrier card 402 having a mezzanine board configuration can be a Common Mezzanine Card (CMC) as specified and set forth in the Institute of Electrical and Electronics Engineers (IEEE) standard P1386. A particular example of an embodiment of carrier card 402 is a PCI mezzanine card (PMC). In other words, carrier card 402 can have a PMC form factor.

Carrier card can include one or more mini-PCI cards 404 with their associated modules 406 to add functionality to computer system 400. Optionally, carrier card 402 can include a bridging module (not shown for clarity) coupled to mini-PCI cards 404 as described above. PMC includes adaptor connector 405, and connector interface 407, which can be a PMC adaptor connector and a PMC connector interface. PMC form factor, PMC adaptor connector, PMC connector interface, including mechanical dimensions, electrical specifications, and the like, are also set forth in IEEE standard P1386.

FIG. 5 depicts a representation 500 of a form factor of a mini-PCI card 504 according to an embodiment of the invention. The mini-PCI card 504 shown in FIG. 5 is representative of a Type I or Type II form factor mini-PCI card 504 as defined by Mini PCI Specification revision I or later as promulgated by the PCI Special Interest Group, Hillsboro, Oreg. Type I form factor includes a Type IA and Type IB form factor, which are also represented by FIG. 5. Type II form factor also includes a Type IIA and Type IIB form factor, which are represented by FIG. 5.

Mini-PCI card 504 can include one or more modules 506 to add functionality to mini-PCI card 504 and computer system as described above. Carrier card 502 includes mini-PCI card interface 509, where mini-PCI card 504 is coupled, and interfaces with carrier card 502 via mini-PCI card interface 509. Type I and Type II form factors, mechanical dimensions of mini-PCI card 504, electrical specifications, and the like, are set forth in Mini PCI Specification revision 1 or later.

Carrier card 502 can also include bridging module (not shown for clarity), where bridging module is coupled to mini-PCI card interface 509. Carrier card 502 can also include more than one mini-PCI card interface 509 and associated mini-PCI cards 504. Mini-PCI card interface 509 can also be coupled to adapter connector (not shown for clarity) on carrier card 502 as described and shown above.

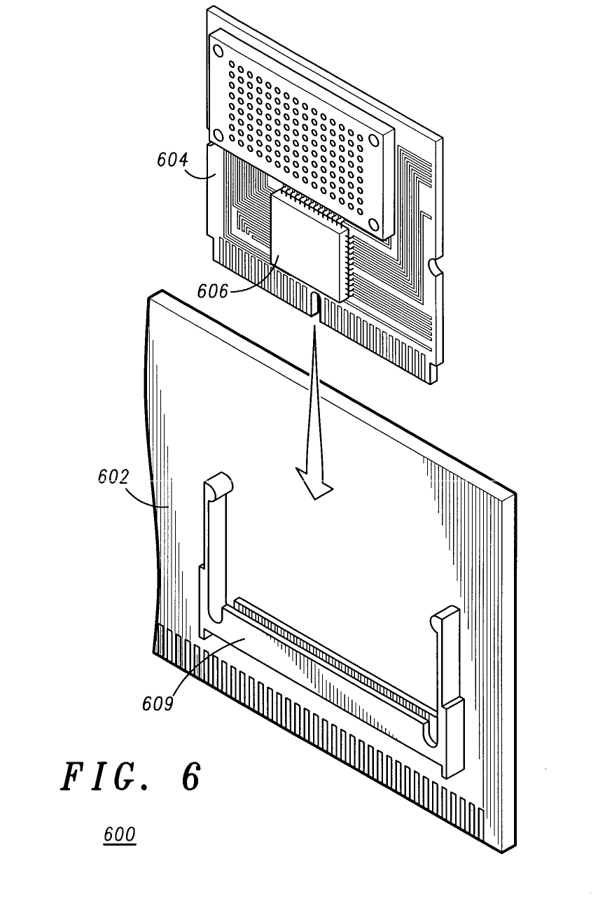

FIG. 6 depicts a representation 600 of a form factor of a mini-PCI card 604 according to another embodiment of the invention. The mini-PCI card 604 shown in FIG. 6 is representative of a Type III form factor mini-PCI card 604 as defined by Mini PCI Specification revision 1 or later as promulgated by the PCI Special Interest Group, Hillsboro, Oreg. Type III form factor includes a Type IIIA and Type IIIB form factor, which are represented by FIG. 6.

Mini-PCI card 604 can include one or more modules 606 to add functionality to mini-PCI card 604 and computer system as described above. Carrier card 602 includes mini-PCI card interface 609, where mini-PCI card 604 is coupled, and interfaces with carrier card 602 via mini-PCI card interface 609. Type III form factors, mechanical dimensions of mini-PCI card 604, electrical specifications, and the like, are set forth in Mini PCI Specification revision 1 or later.

Carrier card 602 can also include bridging module (not shown for clarity), where bridging module is coupled to mini-PCI card interface 609. Carrier card 602 can also include more than one mini-PCI card interface 609 and associated mini-PCI cards 604. Mini-PCI card interface 609 can also be coupled to adapter connector (not shown for clarity) on carrier card 602 as described and shown above.

While we have shown and described specific embodiments of the present invention, further modifications and improvements will occur to those skilled in the art. It is therefore, to be understood that appended claims are intended to cover all such modifications and changes as fall within the true spirit and scope of the invention.

1. A computer system, comprising:
a carrier card; and
a mini-PCI card coupled to the carrier card, wherein the mini-PCI card interfaces with the computer system via the carrier card.

2. The computer system of claim 1, wherein the carrier card has one of a VMEbus, CompactPCI, PMC, PCI, ATCA and APS form factor.

3. The computer system of claim 1, further comprising a connector interface, wherein the carrier card interfaces with the computer system via the connector interface.

4. The computer system of claim 3, wherein the connector interface is one of a PCI connector interface and a PMC connector interface.

5. The computer system of claim 1, wherein the carrier card comprises a bridging module coupled to the mini-PCI card.

6. The computer system of claim 5, wherein the mini-PCI card communicates with the computer system via the bridging module.

7. The computer system of claim 1, wherein the mini-PCI card has one of a type I, type II and type III form factor.

8. A carrier card, comprising:
a mini-PCI card interface for receiving a mini-PCI card; and
an adaptor connector.

9. The carrier card of claim 8, wherein the adaptor connector is one of a PCI connector and a PMC connector.

10. The carrier card of claim 8, wherein the carrier card has one of a VMEbus, CompactPCI, PMC, PCI, ATCA and APS form factor.

11. The carrier card of claim 8, further comprising a bridging module, wherein the bridging module is coupled to the mini-PCI card interface and to the adaptor connector.

12. The carrier card of claim 8, wherein the mini-PCI card interface is designed to receive the mini-PCI card having one of a type I, type II and type III form factor.

13. The carrier card of claim 8, wherein the carrier card is designed to interface with a computer system.

14. A method of interfacing a mini-PCI card to a computer system, comprising:
providing a carrier card;
coupling the mini-PCI card to the carrier card; and
coupling the carrier card to the computer system.

15. The method of claim 14, further comprising the mini-PCI card communicating with the computer system via the carrier card.

16. The method of claim 14, further comprising the carrier card having one of a VMEbus, CompactPCI, PMC, PCI, ATCA and APS form factor.

17. The method of claim 14, further comprising the mini-PCI card having one of a type I, type II and type III form factor.

18. The method of claim 14, wherein coupling the carrier card to the computer system comprises coupling the carrier card to the computer system with an adaptor connector, wherein the adaptor connector is one of a PCI connector and a PMC connector.

19. The method of claim 14, further comprising the mini-PCI card communicating with the computer system via a bridging module, wherein the bridging module is coupled to the carrier card.
